(19) United States
(12) Patent Application Publication
(10) Pub. No.: US 2015/0206783 A1
(43) Pub. Date: Jul. 23, 2015

(54) SYSTEM AMD METHOD FOR SUBSTRATE HOLDING

(71) Applicants: HALE JOHNSON, JERICHO, VT (US); GREGORY GEORGE, COLCHESTER, VT (US)

(72) Inventors: HALE JOHNSON, JERICHO, VT (US); GREGORY GEORGE, COLCHESTER, VT (US)

(73) Assignee: SUSS MICROTEC LITHOGRAPHY, GMBH, Garching (DE)

(21) Appl. No.: 14/597,298

(22) Filed: Jan. 15, 2015

Related U.S. Application Data
(63) Continuation-in-part of application No. 14/330,497, filed on Jul. 14, 2014.
(60) Provisional application No. 61/929,192, filed on Jan. 20, 2014.

(51) Int. Cl. H01L 21/683

(52) U.S. Cl. CPC H01L 21/683; H01L 2221/683

(57) ABSTRACT

A system for mechanically holding a substrate during processing includes a closeable processing chamber and an upper block assembly located inside the processing chamber and configured to hold a wafer via three mechanical holding assemblies. The three mechanical holding assemblies protrude above a cover of the wafer processing chamber and are configured to hold the wafer at an edge of the wafer and to be adjusted from outside of the processing chamber. Two of the mechanical holding assemblies are lockable in position relative to the wafer edge and one of the mechanical holding assemblies is configured to maintain a hold preload on the wafer edge via a preload mechanism.

### CROSS REFERENCE TO RELATED CO-PENDING APPLICATIONS

This application claims the benefit of U.S. provisional application Ser. No. 61/929,192 filed Jan. 20, 2014 and entitled “SYSTEM AND METHOD FOR SUBSTRATE HOLDING”, the contents of which are expressly incorporated herein by reference.

This application is a continuation in part of U.S. application Ser. No. 14/330,497 filed Jul. 14, 2014 and entitled “APPARATUS AND METHOD FOR ALIGNING AND CENTERING WAFERS”, the contents of which are expressly incorporated herein by reference.

### FIELD OF THE INVENTION

The present invention relates to a system and method for substrate holding, and more particularly to a system and a method for mechanically holding a substrate during processing while maintaining the concentrical and rotational alignment of the substrate.

### BACKGROUND OF THE INVENTION

In several wafer bonding processes two or more aligned wafers are held opposite to each other and then are brought into contact with each other. Similarly, in several chemical or mechanical semiconductor processes wafers are held in place while the processing occurs. Some of these semiconductor wafer processes include wafer thinning steps. In particular, for some applications the wafers are thinned down to a thickness of less than 100 micrometers for the fabrication of integrated circuit (IC) devices, or for 3D-integration bonding and for fabricating through wafer vias.

For wafer thicknesses of over 200 micrometers, the wafer is usually held in place with a fixture that utilizes a vacuum chuck or some other means of mechanical attachment. However, for wafer thicknesses of less than 200 micrometer and especially for wafers of less than 100 micrometers, it becomes increasingly difficult to mechanically hold the wafers and to maintain control of the alignment, planarity and integrity of the wafers during processing. In these cases, it is actually common for wafers to develop microfractures and to break during processing. An alternative to mechanical holding of a wafer during a thinning process that results in wafer thicknesses of less than 200 micrometer, involves attaching a first surface of a device wafer (i.e., wafer processed into a device) onto a carrier wafer and then thinning down the exposed opposite device wafer surface. The bond between the carrier wafer and the device wafer is temporary and is removed upon completion of the thinning process and any other processing steps. The temporary bonded pair of the device wafer and carrier wafer is held mechanically during the thinning process.

An alternative to mechanical holding of wafers during processing involves using an electrostatic chuck (e-chuck) for holding the wafers with electrostatic forces. However, e-chucks are usually expensive and complicated devices and they require high voltage supply and cabling. Furthermore, they are usually not applicable for holding glass substrates.

A critical aspect of the above mentioned wafer holding mechanisms involves the positioning and alignment of the held wafers relative to each other. It is desirable to provide an industrial-scale device for holding and supporting wafers during processing, while maintaining the concentrical and rotational alignment of the wafers and preventing fracture, surface damage or warping of the wafers.

### SUMMARY OF THE INVENTION

The invention provides a system and a method for mechanically holding a substrate during processing while maintaining the concentrical and rotational alignment of the substrate.

In general, in one aspect, the invention features, a wafer processing system including a closeable processing chamber and an upper block assembly located inside the processing chamber and configured to hold a wafer via three mechanical holding assemblies. The three mechanical holding assemblies protrude above a cover of the wafer processing chamber and are configured to hold the wafer at an edge of the wafer and to be adjusted from outside of the processing chamber. Two of the mechanical holding assemblies are lockable in position relative to the wafer edge and one of the mechanical holding assemblies is configured to maintain a hold preload on the wafer edge via a preload mechanism.

Implementations of this aspect of the invention include one or more of the following. Each mechanical holding assembly includes a flag and a pivot drive arm and the flag is driven radially to contact the wafer edge via a drive mechanism. In each of the two mechanical holding assemblies that are lockable, a distal edge of the flag is configured to contact the wafer edge and the pivot drive arm is configured to move sidewise to engage a slot formed on a side of a proximal end of the flag with a pin. In the mechanical holding assembly that maintains a hold preload, the preload mechanism includes a high temperature resistant bearing guided linear slide. The drive mechanism in each mechanical holding assembly includes a pneumatically driven piston and a drive arm, and the pneumatically driven piston is connected to the drive arm and is configured to drive the drive arm, and the drive arm is connected to the flag via a shaft and the pivot drive arm. In each of the two mechanical holding assemblies that are lockable, the drive mechanism further includes a brake cylinder that is configured to drive a flexible brake arm and the flexible brake arm is configured to transfer a braking motion to the pivot drive arm via the shaft. The flexible brake arm has a flexure type material that is rigid in-plane and flexible out-of-plane. The flag is plate-shaped and is supported by a chuck comprised in the upper block assembly and has a length dimensioned to span a distance from an outer edge of the chuck to the wafer edge. The distal edge of the flag has a step. The distal edge of the flag is curved. The distal edge of the flag has a curvature matching and complementing the curvature of the wafer edge. The distal edge of the flag has a protective coating configured to protect the wafer edge integrity, to provide damping when the distal edge of the flag touches the wafer edge and to provide positive holding friction between the distal edge of the flag and the wafer edge. The protective coating is made of high temperature resistant polyether-ether ketone (PEEK) coatings, polyimide coatings or Teflon coatings. The side profile of the distal edge of the flag is straight, angled or curved.

In general, in another aspect, the invention features a wafer holding system including three mechanical holding assemblies configured to hold a wafer at an edge of the wafer. Two of the mechanical holding assemblies are lockable in position relative to the wafer edge and one of the mechanical holding assemblies is configured to maintain a hold preload on the wafer edge via a preload mechanism.

The system can be used for holding substrates in vacuum and for holding substrates that are subjects to gravitational forces. The system is also applicable to holding a pair of temporary bonded wafers during processing of the device wafer.

The details of one or more embodiments of the invention are set forth in the accompanying drawings and description below. Other features, objects and advantages of the invention will be apparent from the following description of the preferred embodiments, the drawings and from the claims.

### BRIEF DESCRIPTION OF THE DRAWINGS

Referring to the figures, wherein like numerals represent like parts throughout the several views:

FIG. 1A is a perspective view of a wafer bonder module according to this invention;

FIG. 1B is a cross-sectional view of the wafer bonder module of FIG. 1A along the X-X′ plane;

FIG. 1C is a cross-sectional view of the wafer bonder module of FIG. 1A along the Y-Y′ plane;

FIG. 1D is a detailed cross-sectional view of the upper block assembly (or chamber lid) in area A of the wafer bonder module of FIG. 1B;

FIG. 1E is a schematic diagram of the wafer bonder module of FIG. 1A;

FIG. 2 is a perspective view of a wafer bonder system, in the closed configuration, according to this invention;

FIG. 3 is a perspective view of the wafer bonder system of FIG. 2, in the open configuration;

FIG. 4A depicts the upper block assembly (or chamber lid) of the wafer bonder module of FIG. 2 holding a wafer having a diameter of 200 mm;

FIG. 4B depicts the upper block assembly (or chamber lid) of the wafer bonder module of FIG. 2 holding a wafer having a diameter of 300 mm;

FIG. 5A is a perspective view of the upper block assembly (or chamber lid) of the wafer bonder module of FIG. 2 holding a wafer having a diameter of 200 mm;

FIG. 5B is an enlarged detailed sectional view of area B of the upper block assembly (or chamber lid) of FIG. 5A;

FIG. 5C is an enlarged cross-sectional view of the wafer bonder module of FIG. 2 along the X-X′ plane;

FIG. 6A is an enlarged detailed view area C of the wafer bonder module of FIG. 5C;

FIG. 6B-FIG. 6D depict alternative end surface profiles of flag 112 in FIG. 6A;

FIG. 7A is an enlarged bottom view of the wafer holding assembly 110A of FIG. 4A;

FIG. 7B is an enlarged bottom view of the wafer holding assembly 110A of FIG. 4B;

FIG. 8A is an enlarged top view of the flag drive mechanism for the wafer holding assembly 110A of FIG. 4A;

FIG. 8B is a cross-sectional view of the flag drive mechanism of FIG. 8A;

FIG. 8C is a bottom cross-sectional view of the flag drive mechanism of FIG. 8A; and

FIG. 8D is an enlarged cross-sectional view of the flag drive mechanism of FIG. 8B.

### DETAILED DESCRIPTION OF THE INVENTION

The invention provides a system and a method for mechanically holding a substrate during processing while maintaining the concentrical and rotational alignment of the substrate.

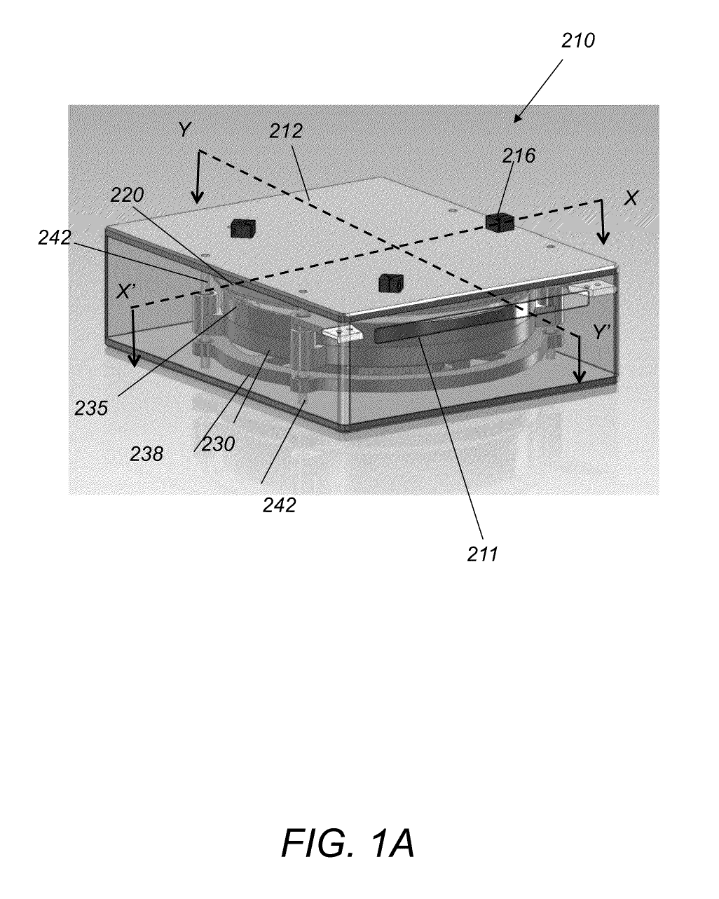

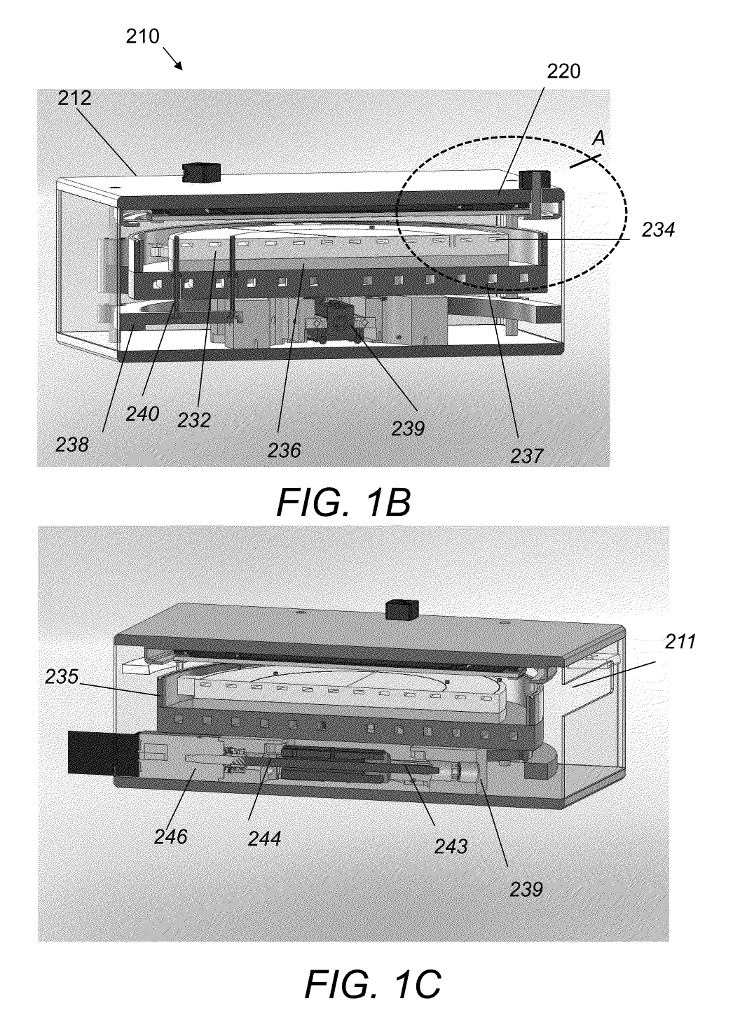

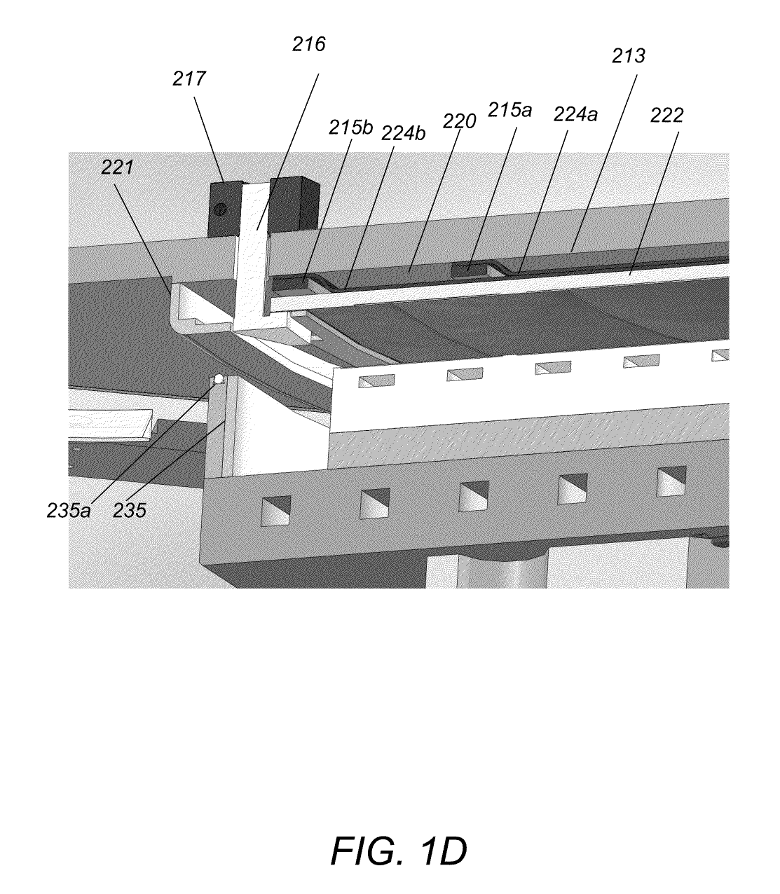

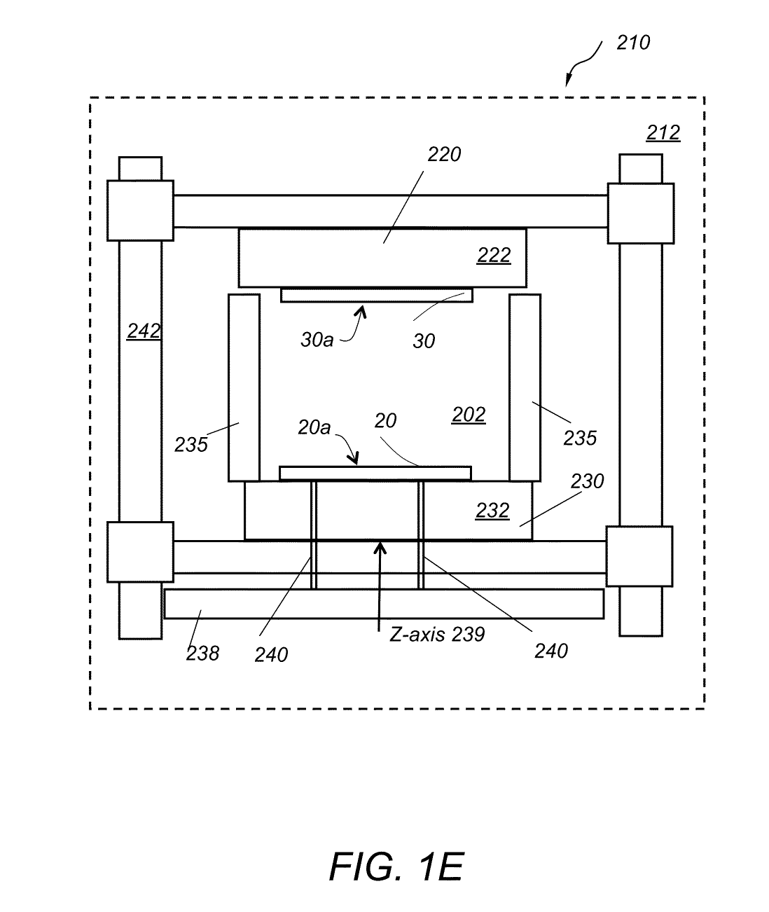

Referring to FIG. 1A-FIG. 1E, a typical wafer bond module 210 includes a housing 212 having a load door 211, an upper block assembly 220 and an opposing lower block assembly 230. The upper and lower block assemblies 220, 230 are movably connected to four Z-guide posts 242. In other embodiments, less than four or more than four Z-guide posts are used. A telescoping curtain seal 235 is disposed between the upper and lower block assemblies 220, 230. A bonding chamber 202 is formed between the upper and lower assemblies 220, 230 and the telescoping curtain seal 235. The curtain seal 235 keeps many of the process components that are outside of the bonding chamber area 202 insulated from the process chamber temperature, pressure, vacuum, and atmosphere. Process components outside of the chamber area 202 include guidance posts 242, Z-axis drive 243, illumination sources, mechanical pre-alignment arms and wafer centering jaws, among others. Curtain 235 also provides access to the bond chamber 202 from any radial direction. A more detailed description of a typical wafer bond module 210 is presented in U.S. application Ser. No. 12/761,044 filed Apr. 15, 2010 and entitled “DEVICE FOR CENTERING WAFERS”, the contents of which are expressly incorporated herein by reference.

Referring to FIG. 1B, the lower block assembly 230 includes a heater plate 232 supporting a wafer 20, an insulation layer 236, a water cooled support flange 237 a transfer pin stage 238 and a Z-axis block 239. Heater plate 232 is a ceramic plate and includes resistive heater elements and integrated air cooling. The heater elements are arranged so that two different heating zones are formed, a main or center zone and an edge zone. The two heating zones are controlled so that the temperature of the heater plate 232 is uniform. Heater plate 232 also includes two different vacuum zones for holding wafers of 200 mm and 300 mm, respectively. The water cooled thermal isolation support flange 237 is separated from the heater plate by the insulation layer 236. The transfer pin stage 238 is arranged below the lower block assembly 230 and is movable supported by the four posts 242. Transfer pin stage 238 supports transfer pins 240 arranged so that they can raise or lower different size wafers. In one example, the transfer pins 240 are arranged so that they can raise or lower 200 mm and 300 mm wafers. Transfer pins 240 are straight shafts and, in some embodiments, have a vacuum feed opening extending through their center. Vacuum drawn through the transfer pin openings holds the supported wafers in place onto the transfer pins during movement and prevents misalignment of the wafers. The Z-axis block 239 includes a precision Z-axis drive 243 with ball screw, linear cam design, a linear encoder feedback 244 for submicron position control, and a servomotor 246 with a gearbox, shown in FIG. 1C.

Referring to FIG. 1D, the upper block assembly 220 includes an upper ceramic chuck 222, a top static chamber wall 221 against which the curtain 235 seals with seal element 235a, a 200 mm membrane layer 224a and a 300 mm membrane layer 224b. The membrane layers 224a, 224b, are clamped between the upper chuck 222 and the top housing wall 213 with clamps 215a, 215b, respectively, and form two separate vacuum zones designed to hold 200 mm and 300 mm wafers, respectively. Membrane layers 224a, 224b are made of elastomer material or metal bellows. The upper ceramic chuck 222 is highly flat and thin. It has low mass and is semi-compliant in order to apply uniform pressure upon the wafers 20, 30. The upper chuck 222 is lightly pre-loaded with membrane pressure against three adjustable leveling clamp/drive assemblies 216. Clamp/drive assemblies 216 are circularly arranged at 120 degrees. The upper chuck 222 is initially leveled while in contact with the lower ceramic heater plate 232, so that it is parallel to the heater plate 232. The clamp/drive assemblies 216 also provide a spherical Wedge Error Compensating (WEC) mechanism that rotates and/or tilts the ceramic chuck 222 around a center point corresponding to the center of the supported wafer without translation. In other embodiments, the upper ceramic chuck 222 positioning is accomplished with fixed leveling/locating pins, against which the chuck 222 is lashed.

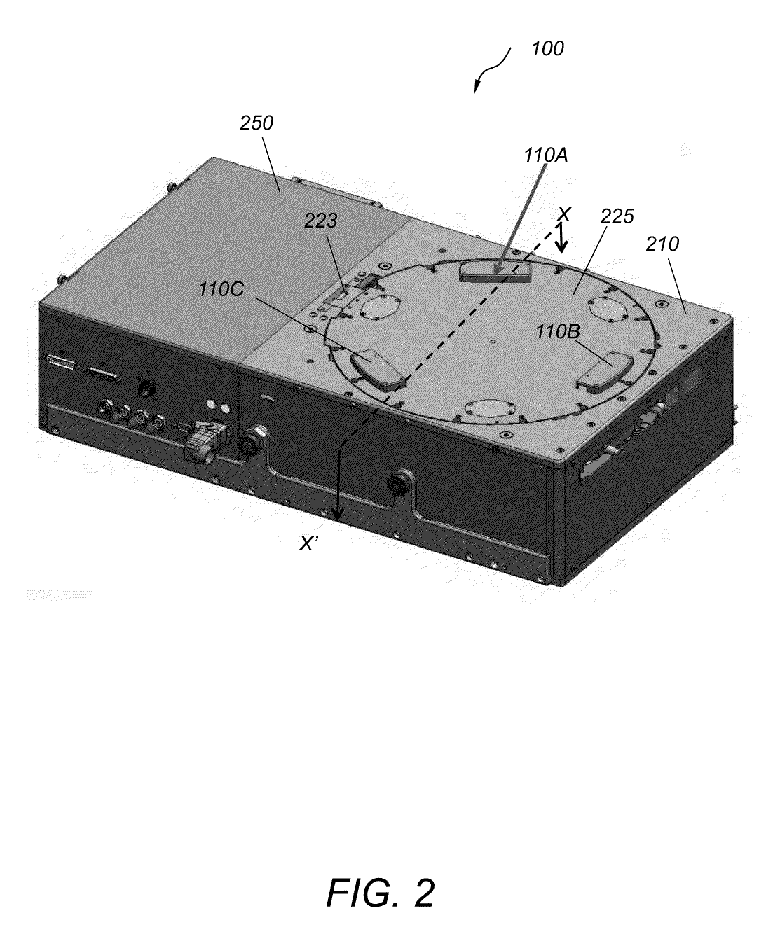

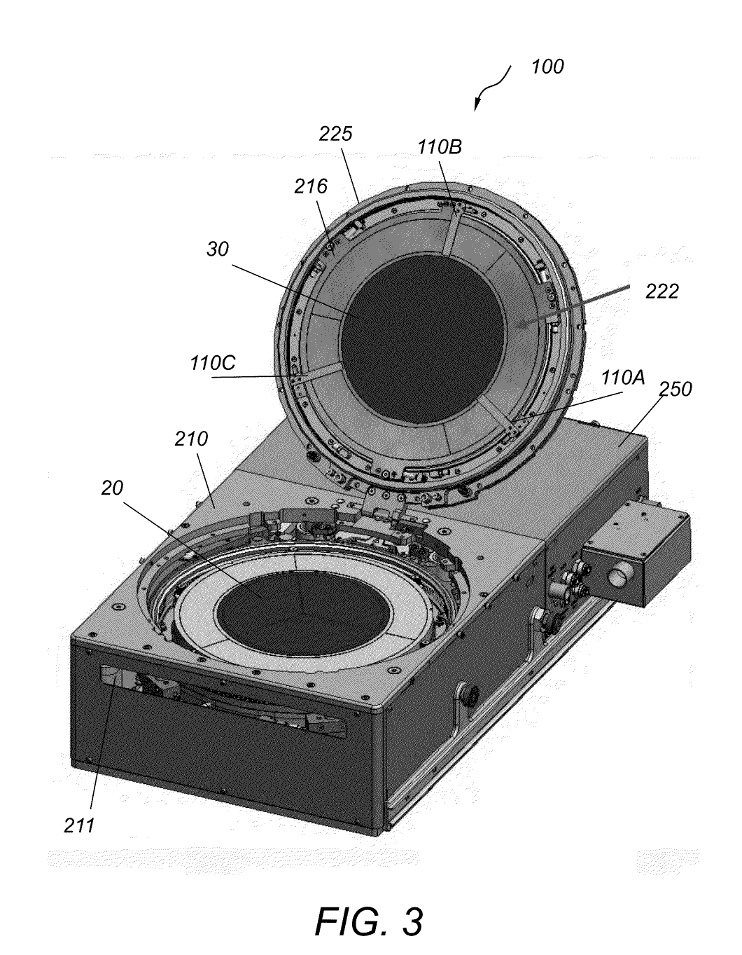

Referring to FIG. 2 and FIG. 3, an improved wafer bond system 100 includes an improved wafer chamber 210 and an electronics unit 250. The wafer bond chamber 210 includes a hinged cover 225 that includes the upper block assembly 220. In this embodiment, wafer 30 is supported onto the upper chuck 222 via three mechanical holding assemblies 110A, 110B, and 110C. The mechanical holding assemblies 110A, 110B and 110C protrude above the cover 225.

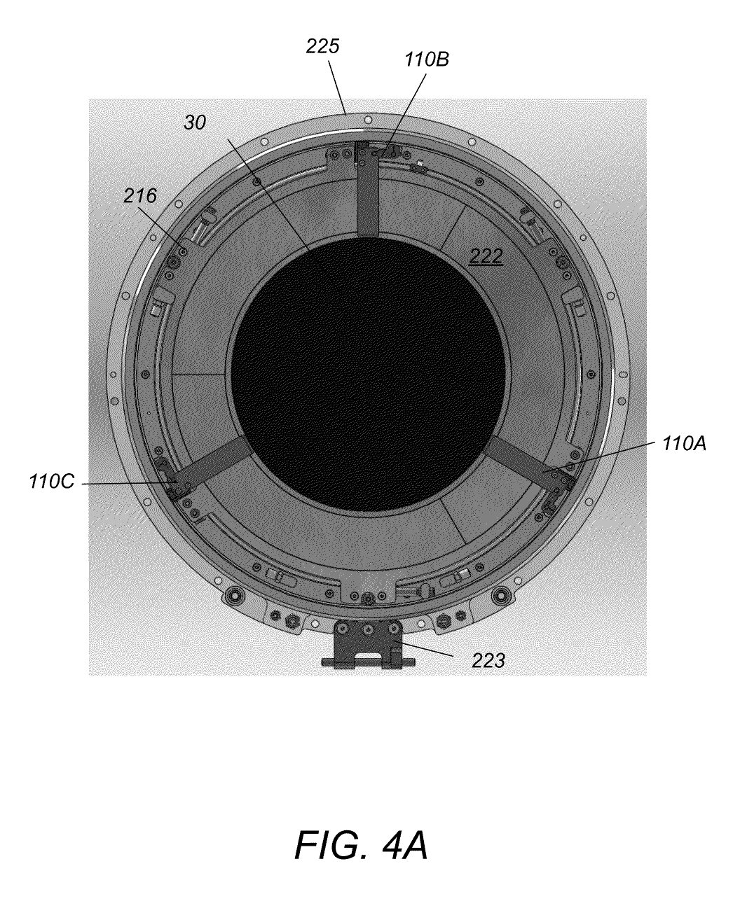

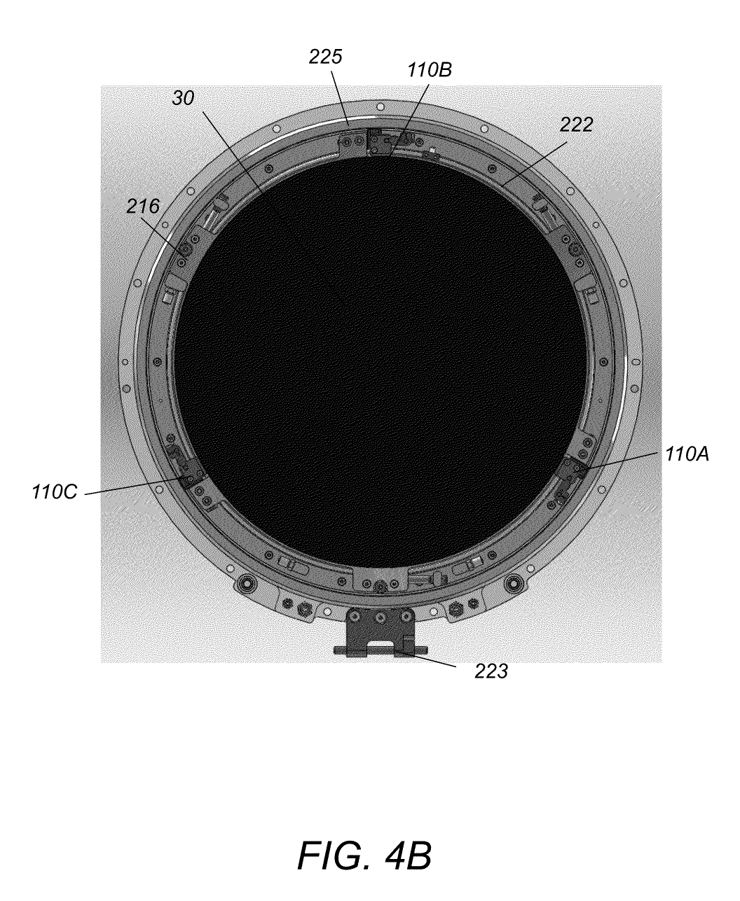

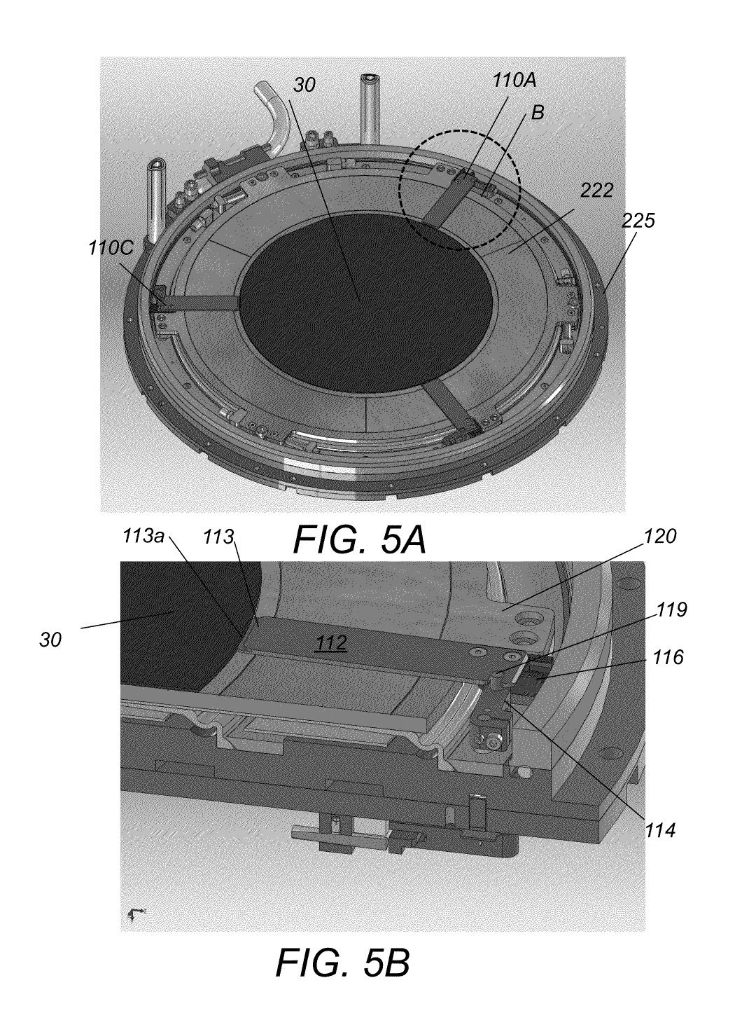

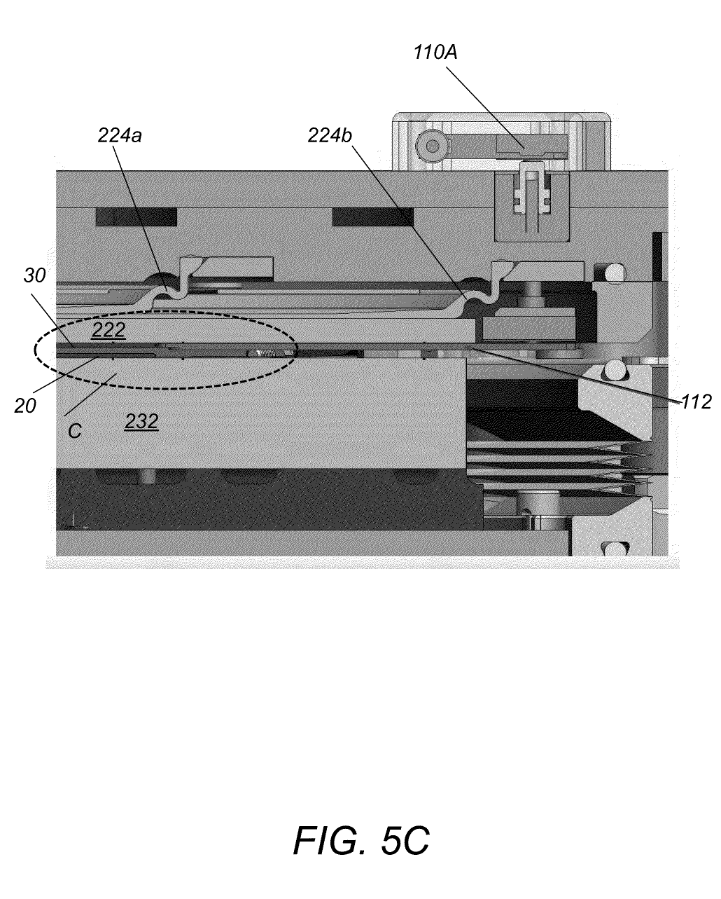

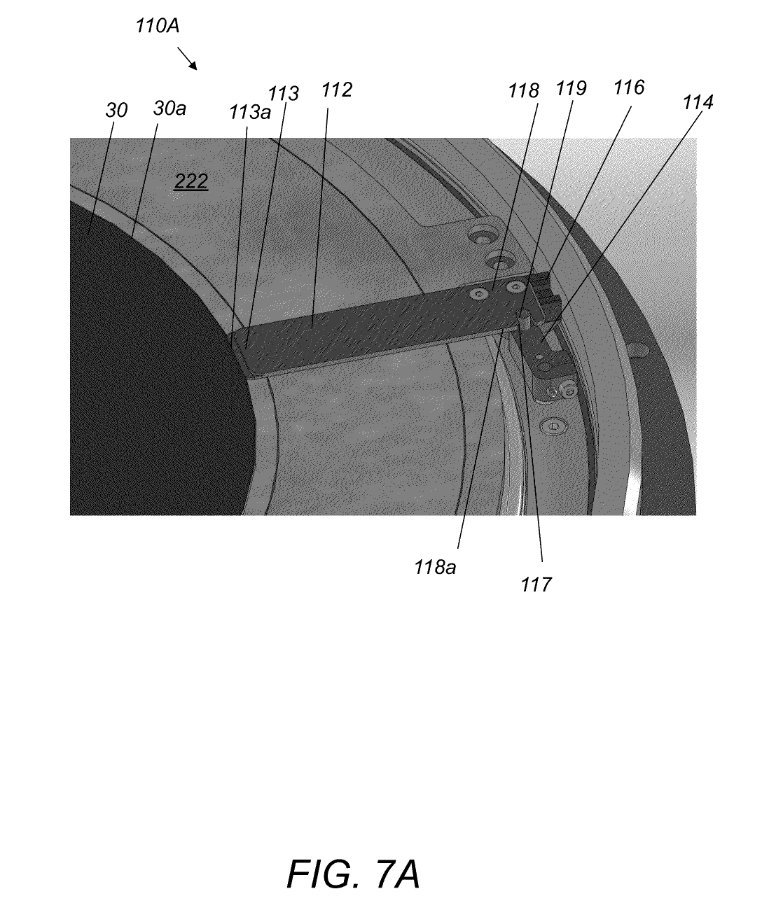

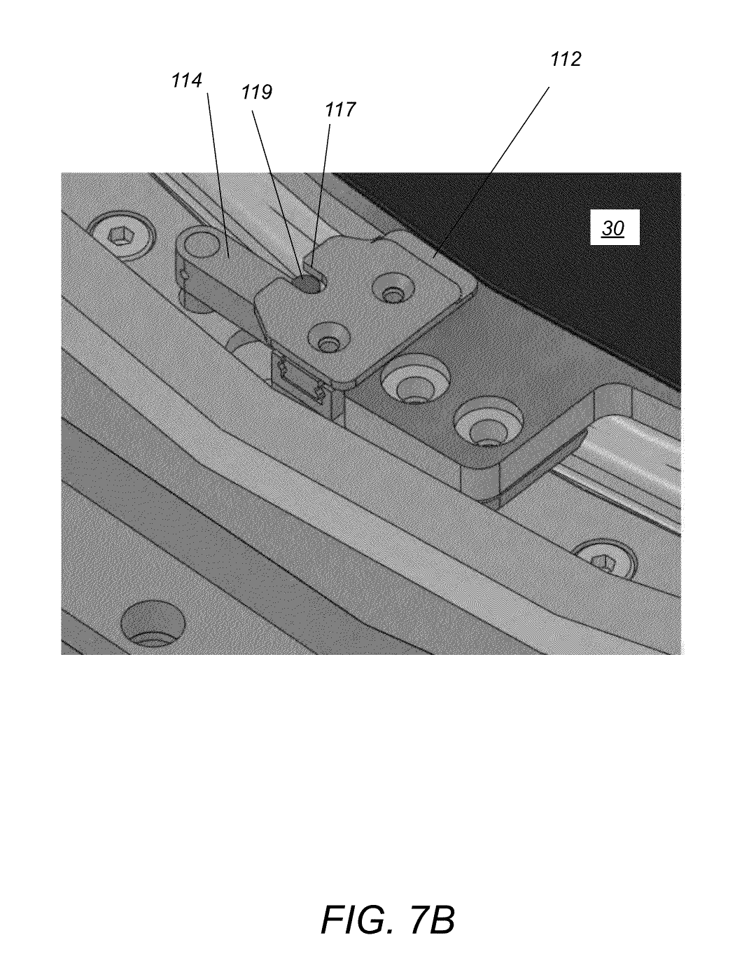

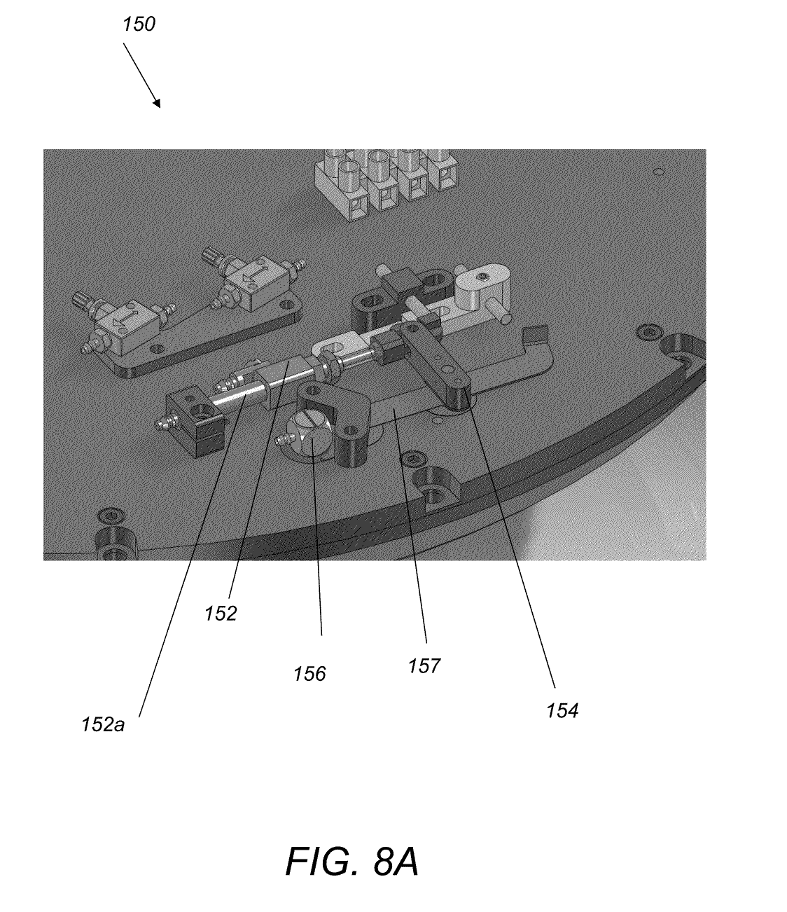

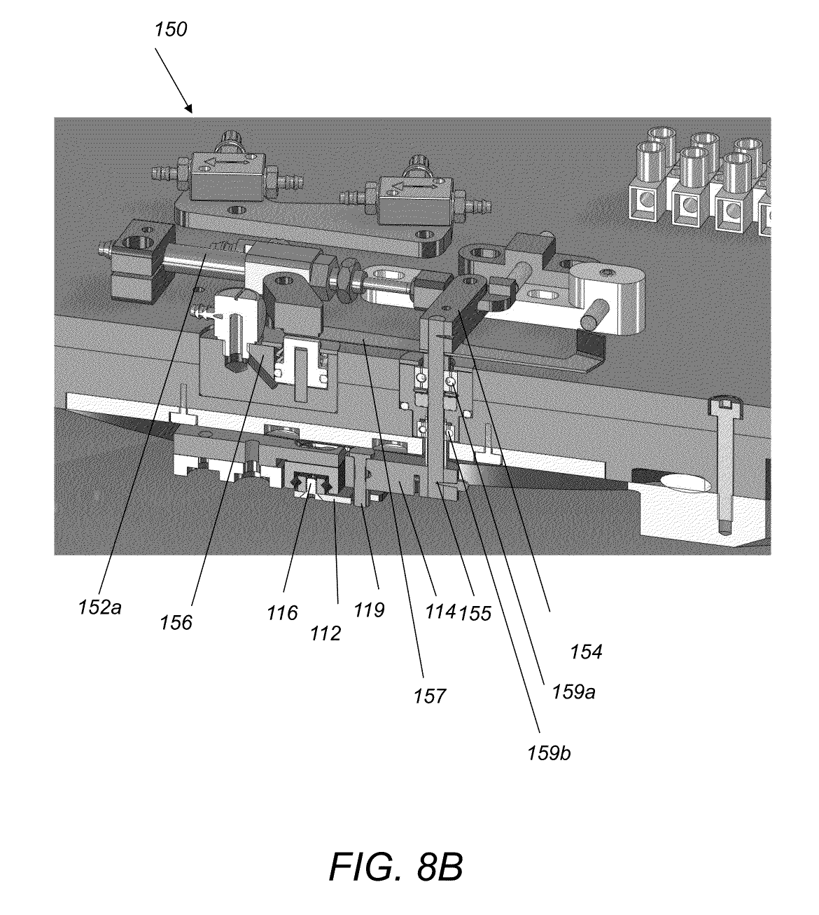

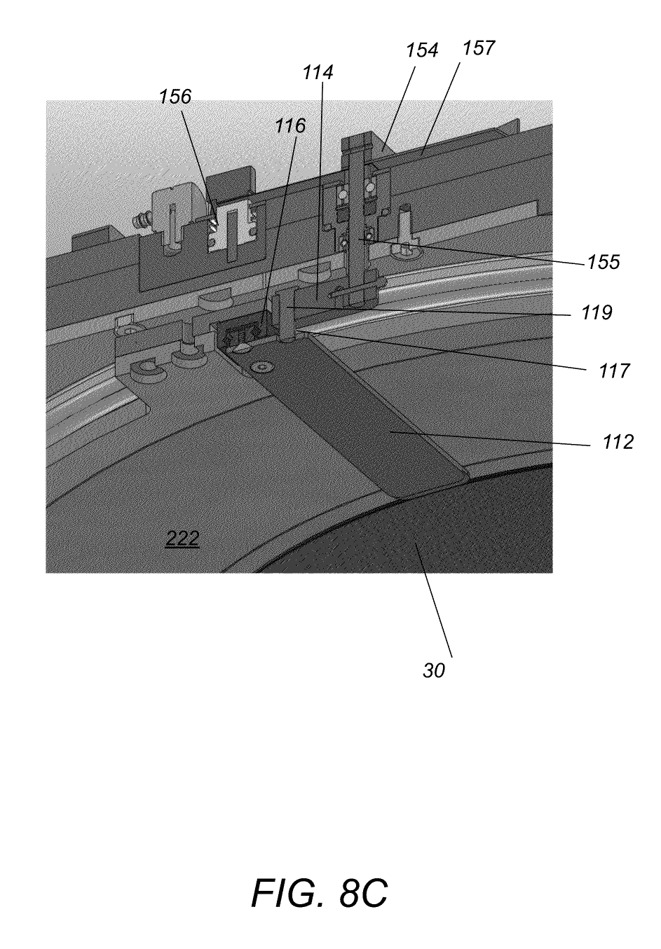

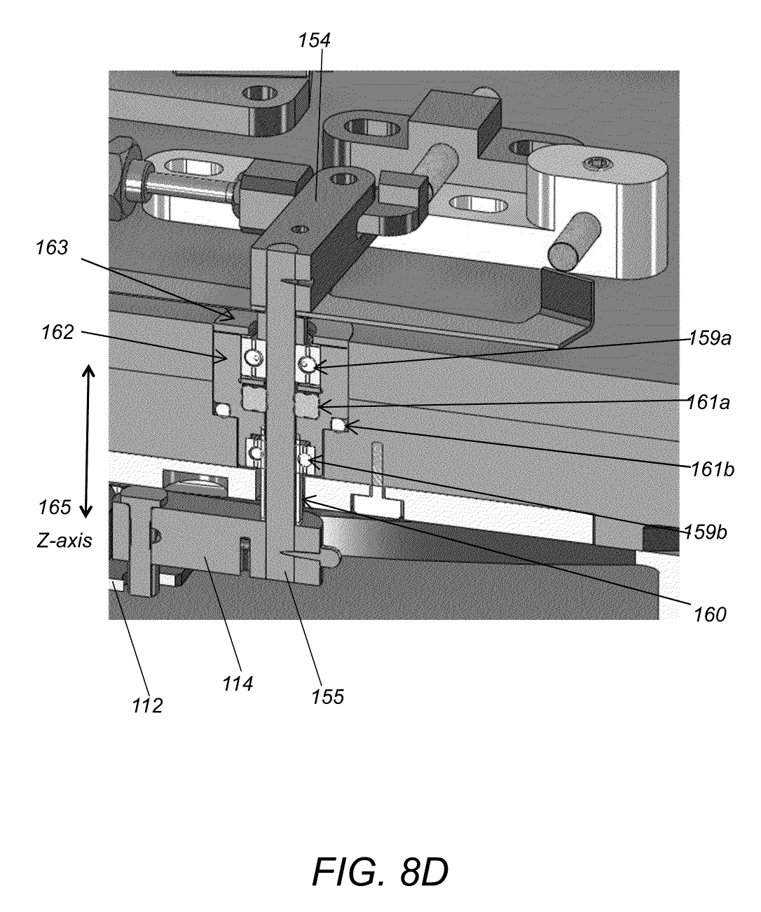

Referring to FIG. 4A-8D, each mechanical holding assembly includes a flag 112 and a pivot drive arm 114. Flag 112 is driven radially to contact the edge 30a of the upper wafer 30 with drive mechanism 150. In two of the holding assemblies 110A, 110C, once the distal edge 113 of the flag 112 contacts the edge of the wafer 30a, pivot drive arm 114 moves sidewise to engage a slot 117 formed on the side 118a of the proximal end 118 of flag 112 with a pin 119, as shown in FIG. 5B and FIG. 7A. This engagement of the pivot arm pin 119 with the flag slot 117 locks the position of flag 112 relative to the wafer edge 30a in the holding assemblies 110A and 110C. In holding assembly 110B, flag 112 maintains a hold preload with a pneumatically or spring driven preload mechanism 160, shown in FIG. 8D. In one example, the preload mechanism includes a high temperature resistant bearing guided linear slide 116, shown in FIG. 7A.

Referring to FIG. 8A-8D, the drive mechanism 150 for each of the holding assemblies 110A, 110B, 110C includes a pneumatically driven piston 152 and a drive arm 154. Pneumatically driven piston 152 includes a cylinder 152a that has an end connected to a first end of the drive arm 154 and is configured to guide the motion of the drive arm 154. Drive arm 154 has a second end that is configured to connect to flag 112 via shaft 155, and pivot drive arm 114, as shown in FIG. 8B and FIG. 8D. Piston 152, drive arm 154 and shaft 155, drive and guide the radial motion of the flag 112. The motion of shaft 155 is guided by ball bearings 159a, 159b that are contained in housing 162, shown in FIG. 8D. Housing 162 is sealed within upper block assembly 220 with O-ring seals 161a, 161b, also shown in FIG. 8D.

The drive mechanism 150 in each of the two holding assemblies 110A, 110C also includes a brake cylinder 156 that drives a flexible brake arm 157. Flexible brake arm 157 transfers a braking motion to pivot drive arm 114 also via shaft 155. Flexible brake arm 157 is made of flexure type material that has an in-plane stiffness and provides positive locking of the pivot drive arm 114. The flexible brake arm 157 is rigid in the in-plane directions (x-y plane of brake arm 157) and is flexible in the out of plane direction (z-axis 165).

In operation, wafer 30 is centered using a centering station as described in U.S. application Ser. No. 12/761,044 filed Apr. 15, 2010 and entitled “DEVICE FOR CENTERING WAFERS”, the contents of which are expressly incorporated herein by reference. Alternatively, wafer 30 is centered via a precise robot wafer placement. The centered wafer 30 is transferred to the top chuck 222 and is held initially with vacuum. Alternatively, the centered wafer may be held via an electrostatic chuck or a combination of vacuum and electrostatic forces.

Next, the flags 112 in the three holding assemblies 110A, 110B, and 110C are driven radially to contact the edge 30a of the wafer. During this step, the vacuum (or electrostatic) holding mechanism is dominant and the radial motion of the flags 112 is secondary. Therefore, the initial position of flags 112 is determined by the handed off position and the holding force. This allows the device to hold circular wafers with various diameter tolerances other than the nominal size. In one example, a device with flags 112 designed to hold a 300 mm wafer might be used to hold wafers having diameters of 301 mm or 299 mm.

Next, the brakes 156, 157 in the flags 112 of assemblies 110A and 110C are applied while the flag 112 in assembly 110B maintains a hold preload with spring 160. The two locked assemblies 110A, 110C define two fixed points and the preload force of assembly 110B holds the wafer positively. The preload force of assembly 110B compensates and maintains positive holding due to any thermal expansion or other deflection in the system during processing. The vacuum (or electrostatic) holding mechanism may be removed at this point.

Next, processing of the wafer takes place while the wafer 30 is held mechanically in place with the three assemblies 110A, 110B, and 110C. Wafer 30 is released at the end of the processing or at any other point by releasing the preload mechanism in assembly 110B.

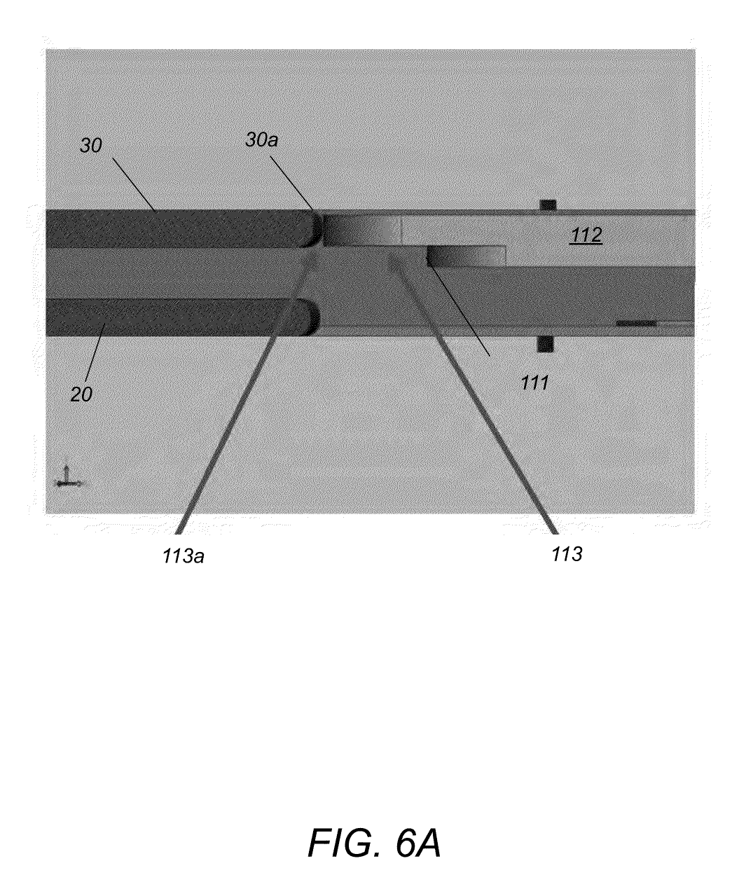

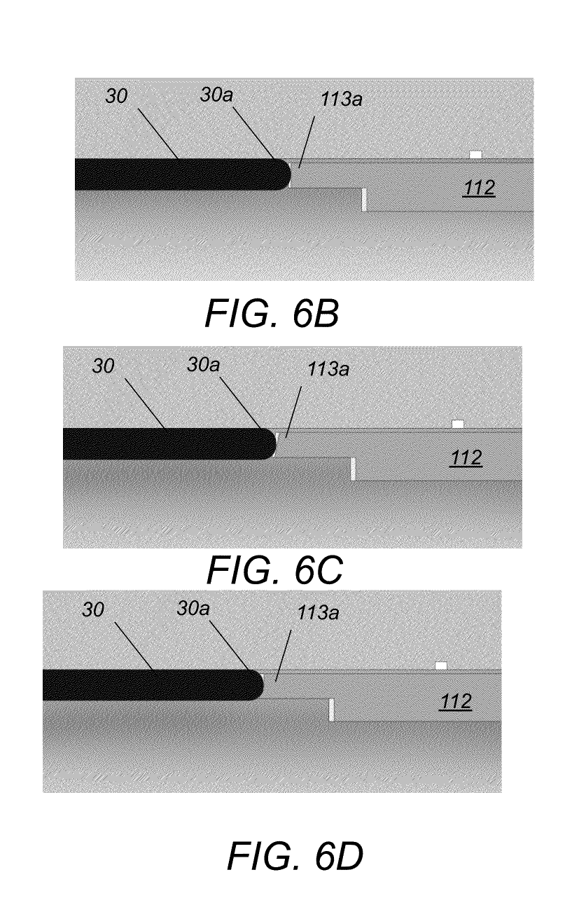

Flag 112 is plate-shaped and has a length dimensioned to span the distance from the outer edge of the upper chuck 222 to the outer edge 30a of the wafer 30. Flags with different lengths are used for holding wafers with a diameter of 200 mm or wafers with a diameter of 300 mm, as shown in FIG. 4A, FIG. 4B, FIG. 7A and FIG. 7B, respectively. The distal edge 113 of flag 112 includes a step 111 that provides enough clearance for the lower wafer 20, when the two wafers 20, 30 are brought into contact, as shown in FIG. 6A. The end surface 113a of the distal edge 113 is curved. The curvature of the end surface 113a matches and complements the curvature of the outer edge 30a of the wafer 30. The end surface 113a of the distal edge 113 is coated with a protective coating that protects the integrity of the wafer edge 30a and provides a damping function when the two edge surfaces 113a and 30a touch each other. The coating also provides increased positive holding friction between the two edge surfaces 113a and 30a. Examples of protective coatings for the edge surface 113a include high temperature resistant polyether-ether ketone (PEEK) coatings, polyimide coatings or Teflon coatings, among others. The side profile of the end surface 113a may be straight, angled or curved, as shown in FIG. 6B, FIG. 6C and FIG. 6D, respectively.

Several embodiments of the present invention have been described. Nevertheless, it will be understood that various modifications may be made without departing from the spirit and scope of the invention. Accordingly, other embodiments are within the scope of the following claims.

What is claimed is:

1. A wafer processing system comprising:
a closeable processing chamber;
an upper block assembly located inside the processing chamber and configured to hold a wafer via three mechanical holding assemblies;
wherein the three mechanical holding assemblies protrude above a cover of the wafer processing chamber and are configured to hold the wafer at an edge of the wafer and to be adjusted from outside of the processing chamber; and
wherein two of the mechanical holding assemblies are lockable in position relative to the wafer edge and one of the mechanical holding assemblies is configured to maintain a hold preload on the wafer edge via a preload mechanism.

2. The system of claim 1, wherein each mechanical holding assembly comprises a flag and a pivot drive arm and wherein the flag is driven radially to contact the wafer edge via a drive mechanism.

3. The system of claim 2, wherein in each of the two mechanical holding assemblies that are lockable, a distal edge of the flag is configured to contact the wafer edge and the pivot drive arm is configured to move sidewise to engage a slot formed on a side of a proximal end of the flag with a pin.

4. The system of claim 2, wherein in the one mechanical holding assembly that maintains a hold preload, the preload mechanism comprises a high temperature resistant bearing guided linear slide.

5. The system of claim 2, wherein the drive mechanism in each mechanical holding assembly comprises a pneumatically driven piston and a drive arm, and wherein the pneumatically driven piston is connected to the drive arm and is configured to drive the drive arm, and wherein the drive arm is connected to the flag via a shaft and the pivot drive arm.

6. The system of claim 5, wherein in each of the two mechanical holding assemblies that are lockable, the drive mechanism further comprises a brake cylinder that is configured to drive a flexible brake arm and the flexible brake arm is configured to transfer a braking motion to the pivot drive arm via the shaft.

7. The system of claim 6, wherein the flexible brake arm comprises a flexure type material that is rigid in-plane and flexible out-of-plane.

8. The system of claim 2, wherein the flag is plate-shaped and is supported by a chuck comprised in the upper block assembly and has a length dimensioned to span a distance from an outer edge of the chuck to the wafer edge.

9. The system of claim 3, wherein the distal edge of the flag comprises a step.

10. The system of claim 3, wherein the distal edge of the flag is curved.

11. The system of claim 10, wherein the distal edge of the flag comprises a curvature matching and complementing the curvature of the wafer edge.

12. The system of claim 3, wherein the distal edge of the flag comprises a protective coating configured to protect the wafer edge integrity, to provide damping when the distal edge of the flag touches the wafer edge and to provide positive holding friction between the distal edge of the flag and the wafer edge.

13. The system of claim 12, wherein the protective coating comprises one of high temperature resistant polyether-ether ketone (PEEK) coatings, polyimide coatings or Teflon coatings.

14. The system of claim 3, wherein the distal edge of the flag is straight, angled or curved.

15. A wafer holding system comprising:
three mechanical holding assemblies configured to hold a wafer at an edge of the wafer; and
wherein two of the mechanical holding assemblies are lockable in position relative to the wafer edge and one of the mechanical holding assemblies is configured to maintain a hold preload on the wafer edge via a preload mechanism.

16. The system of claim 15, wherein each mechanical holding assembly comprises a flag and a pivot drive arm and wherein the flag is driven radially to contact the wafer edge via a drive mechanism.

17. The system of claim 16, wherein in each of the two mechanical holding assemblies that are lockable, a distal edge of the flag is configured to contact the wafer edge and the pivot drive arm is configured to move sidewise to engage a slot formed on a side of a proximal end of the flag with a pin.

18. The system of claim 16, wherein in the one mechanical holding assembly that maintains a hold preload, the preload mechanism comprises a high temperature resistant bearing guided linear slide.

19. The system of claim 16, wherein the drive mechanism in each mechanical holding assembly comprises a pneumatically driven piston and a drive arm, and wherein the pneumatically driven piston is connected to the drive arm and is configured to drive the drive arm, and wherein the drive arm is connected to the flag via a shaft and the pivot drive arm.

20. The system of claim 19, wherein in each of the two mechanical holding assemblies that are lockable, the drive mechanism further comprises a brake cylinder that is configured to drive a flexible brake arm and the flexible brake arm is configured to transfer a braking motion to the pivot drive arm via the shaft.

21. The system of claim 20, wherein the flexible brake arm comprises a flexure type material that is rigid in-plane and flexible out-of-plane.

22. The system of claim 16, wherein the flag is plate-shaped and is supported by a chuck and has a length dimensioned to span a distance from an outer edge of the chuck to the wafer edge.
